(19) United States
(12) Patent Application Publication
(10) Pub. No.: US 2014/0248770 A1
(43) Pub. Date: Sep. 4, 2014

(54) MICROWAVE-ASSISTED HEATING OF STRONG ACID SOLUTION TO REMOVE NICKEL PLATINUM/PLATINUM RESIDUES

(71) Applicant: GLOBALFOUNDRIES INC., Grand Cayman (KY)

(72) Inventors: Clemens FITZ, Dresden (DE); Sven METZGER, Dresden (DE); Paul R. BESSER, Sunnyvale, CA (US); Vincent SIH, Dresden (DE); Anh DUONG, Fremont, CA (US)

(73) Assignee: GLOBALFOUNDRIES Inc., Grand Cayman (KY)

(21) Appl. No.: 13/782,309

(22) Filed: Mar. 1, 2013

(51) Int. Cl. B08B 3/10; H01L 21/768

(52) U.S. Cl. CPC B08B 3/10; H01L 21/76838
USPC 438/664; 134/95.1

(57) ABSTRACT

A method is provided for removing residual Ni/Pt and/or Pt from a semiconductor substrate in a post salicidation cleaning process using microwave heating of a stripping solution. Embodiments include depositing a Ni/Pt layer on a semiconductor substrate; annealing the deposited Ni/Pt layer, forming a nickel/platinum silicide and residual Ni/Pt and/or Pt; removing the residual Ni/Pt and/or Pt from the semiconductor substrate by: microwave heating a strong acid solution in a non-reactive container; exposing the residual Ni/Pt and/or Pt to the microwave heated strong acid solution; and rinsing the semiconductor substrate with water H₂O.

### TECHNICAL FIELD

The present disclosure relates to semiconductor devices including nickel/platinum (Ni/Pt) silicide. The present disclosure is particularly applicable to semiconductor devices having Ni/Pt silicide for 28 nanometer (nm) and/or 32 nm technology nodes.

### BACKGROUND

During nickel platinum silicide (NiPtSi) electrode contact processing and after the first thermal treatment to form Ni rich silicide, excessive Ni will be removed by a strong acid solution such as a mixture of sulfuric acid-hydrogen peroxide (SPM). A second annealing step is required to convert the Ni/Pt to low resistivity NiPtSi. The second annealing step is then followed by a heated Aqua Regia (1:4), SPM, or nitric acid (HNO₃) treatment to remove excessive Ni/Pt and/or Pt residues. This post salicidation clean process has to be selective towards all possibly exposed materials such as silicon nitride (Si₃N₄) (spacers), silicon oxide (SiO₂) (field oxide), NiPtSi (contact electrodes), and nickel platinum silicide germanium (NiPtSiGe) (contact electrodes of source/drain for strain applications).

The standard heating process for the Ni/Pt strip includes using a bath heater to heat the Aqua Regia or the SPM solution for more than 30 minutes to the desired temperature of 130° C. to 180° C. Further, although the HNO₃ process temperature may not be as hot as the Aqua Regia or the SPM process temperature, for example 40° C. to 60° C. compared to 130° C. to 180° C., Ni/Pt strip processes using HNO₃ still require at least 15 minutes to 30 minutes in a bath heater to reach the desired temperature before processing the wafer. Moreover, heating Aqua Regia, for example, for a long period of time leads to the loss of hydrogen chloride (HCl), which causes the solution to become inactive. Similarly, heating SPM or HNO₃ for a long period requires constant monitoring of the concentrations of sulfuric acid (H₂SO₄) and HNO₃, respectively, due to evaporation during the heating process.

A need therefore exists for methodology enabling a shorter heating of Aqua Regia, SPM, and HNO₃ for stripping Ni/Pt and/or Pt residues from a semiconductor substrate to prevent evaporation, and the associated apparatus.

### SUMMARY

An aspect of the present disclosure is a method of removing residual Ni/Pt and/or Pt from a semiconductor substrate in a post salicidation cleaning process using microwave heating of a stripping solution.

Another aspect of the present disclosure is an apparatus including a microwave heater for heating a strong acid solution and a means for applying the solution to residual Ni/Pt and/or Pt.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: depositing a Ni/Pt layer on a semiconductor substrate; annealing the deposited Ni/Pt layer, forming a nickel/platinum silicide and residual Ni/Pt and/or Pt; removing the residual Ni/Pt and/or Pt from the semiconductor substrate by: microwave heating a strong acid solution in a non-reactive container; exposing the residual Ni/Pt and/or Pt to the microwave heated strong acid solution; and rinsing the semiconductor substrate with water (H₂O).

Aspects of the present disclosure include heating a strong acid solution of Aqua Regia (1:4), SPM, or HNO₃. Other aspects include microwave heating the strong acid solution at 150 watts (W) to 180 W. Further aspects include microwave heating the strong acid solution for 1 minute to 5 minutes. Additional aspects include microwave heating the Aqua Regia or SPM to a temperature of 130° C. to 180° C. Further aspects include microwave heating the HNO₃ to a temperature of 40° C. to 60° C. Another aspect includes exposing the residual Ni/Pt and/or Pt to the microwave heated strong acid solution for 1 minute to 3 minutes. Other aspects include continuing microwave heating the strong acid solution to maintain the temperature of the heated strong acid solution during exposure of the residual Ni/Pt and/or Pt to the heated strong acid solution. Additional aspects include rinsing the semiconductor substrate with H₂O at a temperature of 20° C. to 60° C. Another aspect includes rinsing the semiconductor substrate with the H₂O for 1 minute to 30 minutes.

Another aspect of the present disclosure is an apparatus including: a non-reactive container; a strong acid solution in the non-reactive container; a microwave heater for heating the strong acid solution in the non-reactive container; a means for applying the strong acid solution to residual Ni/Pt and/or Pt on a semiconductor substrate; and a H₂O bath for rinsing the semiconductor substrate. Aspects of the apparatus include the microwave heater heating the strong acid solution of Aqua Regia or SPM to a temperature of 130° C. to 180° C. Other aspects include the microwave heater heating the strong acid solution of HNO₃ to a temperature of 40° C. to 60° C. Further aspects include a wet bench or a single wafer process tool for applying the strong acid solution to the residual Ni/Pt and/or Pt. Additional aspects include a non-reactive container made of Teflon.

Another aspect of the present disclosure is a method including: depositing a Ni/Pt layer on a semiconductor substrate; annealing the deposited Ni/Pt layer, forming a nickel/platinum silicide and residual Ni/Pt and/or Pt; removing the residual Ni/Pt and/or Pt from the semiconductor substrate by: microwave heating Aqua Regia, SPM, HNO₃ in a Teflon container for 1 minute to 5 minutes at 150 W to 180 W; exposing the residual Ni/Pt and/or Pt to the microwave heated Aqua Regia, SPM, or HNO₃ for 1 minute to 3 minutes; and rinsing the semiconductor substrate with H₂O. Other aspects include microwave heating Aqua Regia or SPM to 130° C. to 180° C. Further aspects include microwave heating HNO₃ to 40° C. to 60° C. Additional aspects include continuing microwave heating during exposure of the residual Ni/Pt and/or Pt to the Aqua Regia, SPM, or HNO₃. Further aspects include rinsing the semiconductor substrate with H₂O at 20° C. to 60° C. for 2 minutes.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 illustrates a current process flow for removing residual Ni/Pt and/or Pt from a semiconductor substrate in a post salicidation cleaning process;

FIG. 2 illustrates a process flow for removing residual Ni/Pt and/or Pt from a semiconductor substrate in a post salicidation cleaning process, in accordance with an exemplary embodiment; and

FIG. 3 schematically illustrates an apparatus, in accordance with an exemplary embodiment of the present disclosure.

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of Aqua Regia, SPM, or HNO₃ evaporating and/or becoming inactive attendant upon a lengthy heating process during residual Ni/Pt and/or Ni removal. In accordance with embodiments of the present disclosure, Aqua Regia, SPM, or HNO₃ is microwave heated for a short period time, for example 1 minute to 5 minutes, before being applied to the residual Ni/Pt and/or Pt. As a result, the Aqua Regia, SPM, or HNO₃ will not evaporate and, therefore, will not require constant monitoring.

Methodology in accordance with embodiments of the present disclosure includes depositing a Ni/Pt layer on a semiconductor substrate; annealing the deposited Ni/Pt layer, forming a nickel/platinum silicide and residual Ni/Pt and/or Pt; removing the residual Ni/Pt and/or Pt from the semiconductor substrate by: microwave heating a strong acid solution in a non-reactive container; exposing the residual Ni/Pt and/or Pt to the microwave heated strong acid solution; and rinsing the semiconductor substrate with water H₂O.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

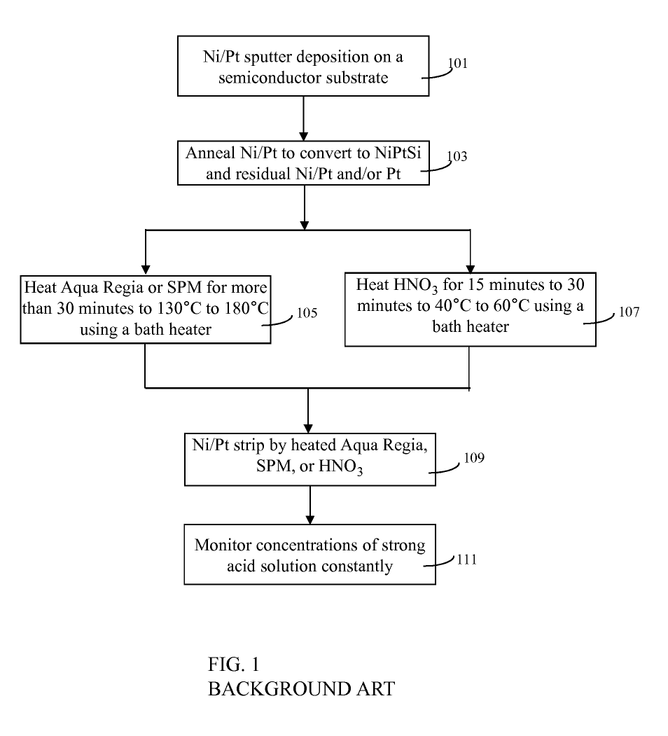

FIG. 1 illustrates a current process flow for removing residual Ni/Pt and/or Pt from a semiconductor substrate in a post salicidation cleaning process. During NiPtSi contact electrode processing, Ni with, for example, 10% Pt is first sputter deposited over an entire semiconductor substrate as shown at step 101 and a first rapid thermal anneal (RTA) (not shown for illustrative purposes) is then performed to form Ni rich silicide. Next, unreacted Ni (Ni that is not on silicon) is stripped by a SPM clean (not shown for illustrative purposes). Adverting to step 103, a second RTA is performed to convert the Ni/Pt to the low resistivity NiPtSi. Aqua Regia or SPM is then heated for more than 30 minutes in a bath heater to the desired temperature of 130° C. to 180° C. as depicted in step 105. Alternatively, in step 107, HNO₃ is heated for 15 to 30 minutes in a bath heater to the desired temperature of 40° to 60°. Averting to step 109, the residual Ni/Pt and/or Pt is stripped by exposing the Ni/Pt and/or Pt to the heated Aqua Regia, SPM, or HNO₃ solutions. Due to the long heating time, the strong acid solutions in either step 105 or 107 must be constantly monitored due to evaporation as shown in step 111.

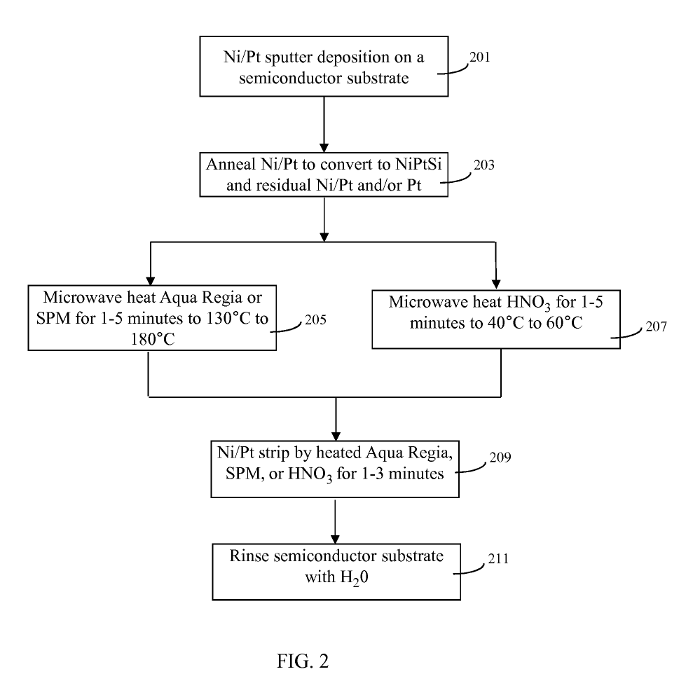

Illustrated in FIG. 2 is a process flow for removing residual Ni/Pt and/or Pt from a semiconductor substrate in a post salicidation cleaning process, in accordance with embodiments of the present disclosure. The initial process flow is similar to that of the process flow illustrated in FIG. 1. Adverting to step 201, during NiPtSi contact electrode processing, Ni with, for example, 10% Pt is sputter deposited over an entire semiconductor substrate. A first RTA (not shown for illustrative purposes) is then performed to form Ni rich silicide. Next, unreacted Ni is stripped by a SPM clean (not shown for illustrative purposes). In step 203, a second RTA is performed to convert the Ni/Pt to the low resistivity NiPtSi.

Averting to step 205, a strong acid solution of Aqua Regia solution having a 4 to 1 ratio or SPM is microwave heated in a non-reactive container that can withstand the respective solutions and does not absorb microwaves, for example a Teflon container. More specifically, the Aqua Regia or the SPM solution is heated to a temperature of 130° C. to 180° C. for 1 minute to 5 minutes using a microwave heater operating at 150 W to 180 W. Alternatively, in step 207, a strong acid solution of HNO₃ is microwave heated in a non-reactive container that can withstand HNO₃ and does not absorb microwaves, for example a Teflon container, to a temperature of 40° C. to 60° C. for 1 minute to 5 minutes using a microwave heater operating at 150 W to 180 W.

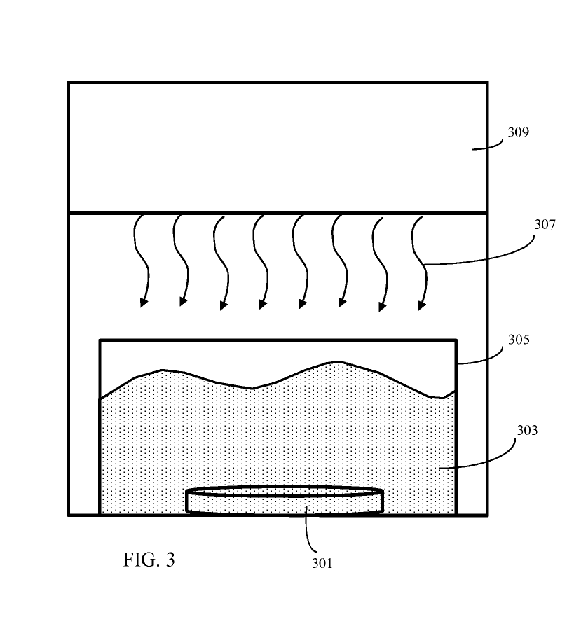

As shown in step 209, the residual Ni/Pt and/or Pt resulting from the second RTA (step 203) is removed from the semiconductor substrate by exposing the residual Ni/Pt and/or Pt to the microwave heated strong acid solution of Aqua Regia, SPM, or HNO₃ for 1 minute to 3 minutes. More specifically, once the strong acid solution reaches the desired temperature, for example 130° C. to 180° C. for Aqua Regia or SPM or 40° to 60° C. for HNO₃, it is applied to the residual Ni/Pt and/or Pt on the semiconductor substrate for example using a wet bench or a single wafer process tool (neither shown for illustrative purposes). Further, during step 209, microwave heat can optionally be applied again to the strong acid solution to maintain the desired temperature of the heated strong acid solution during exposure of the residual Ni/Pt and/or Pt to the heated. strong acid solution, as illustrated in FIG. 3. In step 211, the semiconductor substrate is then rinsed with H₂0 at a temperature of 20° C. to 60° C., for example 25° C., for 1 minute to 30 minutes, for example 2 minutes.

Adverting to the apparatus of FIG. 3, a semiconductor substrate 301 having residual Ni/Pt and/or Pt is exposed to a heated strong acid solution 303, for example Aqua Regia, SPM, or HNO3, contained in a non-reactive container 305, for example a Teflon container. The semiconductor substrate 301 is exposed to the heated strong acid solution 303 for 1 minute to 3 minutes in a wet bench or a single wafer process tool (neither shown for illustrative purposes). During this process, microwave heating 307 can also be applied as depicted in FIG. 3 to maintain the desired temperature, for example 130° C. to 180° C. for Aqua Regia or SPM or 40° C. to 60° C. for HNO₃. More specifically, the container 305 containing the semiconductor substrate 301 and the strong acid solution 303 may be heated by a microwave heater 309 operating at 150 W to 180 W. Once the semiconductor substrate 301 has been exposed to the heated strong acid solution for 1 minute to 3 minutes, the semiconductor substrate 301 is rinsed in a H₂O bath (not shown for illustrative purposes) having a temperature of 20° C. to 60° C., for example 25° C., for 1 minute to 30 minutes, for example 2 minutes.

The embodiments of the present disclosure can achieve several technical effects including shorter heating times for the strong acid solution of Aqua Regia, SPM, or HNO3 used in the Ni/Pt strip process, which prevents evaporation and the need for constant monitoring. Moreover, the strong acid solution can be applied to the semiconductor substrate in a wet bench or in a single wafer process tool. Embodiments of the present disclosure enjoy utility in various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure enjoys industrial applicability in any of various types of highly integrated semiconductor devices including 28 nm and/or 32 nm technology nodes.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
depositing a nickel (Ni)/platinum (Pt) layer on a semiconductor substrate;
annealing the deposited Ni/Pt layer, forming a nickel/platinum silicide and residual Ni and/or residual Pt;
removing the residual Ni by exposing the nickel/platinum silicide to an acid;
performing a second anneal;
removing the residual Pt from the semiconductor substrate by:
microwave heating a strong acid solution in a non-reactive container;
exposing the residual Pt to the microwave heated strong acid solution; and
rinsing the semiconductor substrate with water (H₂O).

2. The method according to claim 1, wherein the acid comprises sulfuric acid and hydrogen peroxide (SPM) and the strong acid solution comprises Aqua Regia (1:4), SPM, or nitric acid (HNO₃).

3. The method according to claim 1, comprising microwave heating the strong acid solution at 150 watts (W) to 180 W.

4. The method according to claim 3, comprising microwave heating the strong acid solution for 1 minute to 5 minutes.

5. The method according to claim 4, wherein the strong acid solution comprises Aqua Regia or SPM, the method comprising microwave heating the Aqua Regia or SPM to a temperature of 130° C. to 180° C.

6. The method according to claim 3, wherein the strong acid solution comprises HNO₃, the method comprising microwave heating the HNO₃ to a temperature of 40° C. to 60° C.

7. The method according to claim 1, comprising exposing the residual Pt to the microwave heated strong acid solution for 1 minute to 3 minutes.

8. The method according to claim 7, further comprising continuing microwave heating the strong acid solution to maintain the temperature of the heated strong acid solution during exposure of the residual Pt to the heated strong acid solution.

9. The method according to claim 1, comprising rinsing the semiconductor substrate with H₂O at a temperature of 20° C. to 60° C.

10. The method according to claim 9, comprising rinsing the semiconductor substrate with the H₂O for 1 minute to 30 minutes.

11. An apparatus comprising:
a non-reactive container;
a strong acid solution in the non-reactive container;
a microwave heater for heating the strong acid solution in the non-reactive container;
a means for applying the strong acid solution to residual nickel (Ni)/platinum (Pt) and/or Pt on a semiconductor substrate; and
a water (H2O) bath for rinsing the semiconductor substrate.

12. The apparatus according to claim 11, wherein the strong acid solution comprises Aqua Regia or sulfuric acid and hydrogen peroxide (SPM) and the microwave heater heats the strong acid solution to a temperature of 130° C. to 180° C.

13. The apparatus according to claim 11, wherein the strong acid solution comprises nitric acid (HNO3) and the microwave heater heats the strong acid solution to a temperature of 40° C. to 60° C.

14. The apparatus according to claim 11, wherein the means for applying the strong acid solution to the residual Ni/Pt and/or Pt comprises a wet bench or a single wafer process tool.

15. The apparatus according to claim 11, wherein the non-reactive container comprises a Teflon container.

16. A method comprising:
depositing a nickel (Ni)/platinum (Pt) layer on a semiconductor substrate;
annealing the deposited Ni/Pt layer, forming a nickel/platinum silicide and residual Ni, and/or residual Pt;
removing the residual Ni by exposing the nickel/platinum silicide to a first sulfuric acid and hydrogen peroxide (SPM);
performing a second anneal;
removing the residual Pt from the semiconductor substrate by:
microwave heating Aqua Regia, a second SPM, or nitric acid (HNO₃) in a Teflon container for 1 minute to 5 minutes at 150 Watts (W) to 180 W;
exposing the residual Pt to the microwave heated Aqua Regia, the second SPM, or HNO₃ for 1 minute to 3 minutes; and
rinsing the semiconductor substrate with water (H₂O).

17. The method according to claim 16, comprising microwave heating Aqua Regia or the second SPM to 130° C. to 180° C.

18. The method according to claim 16, comprising microwave heating HNO₃ to 40° C. to 60° C.

19. The method according to claim 16, comprising continuing microwave heating during exposure of the residual Pt to the Aqua Regia, the second SPM, or HNO₃.

20. The method according to claim 16, comprising rinsing the semiconductor substrate with H₂O at 20° C. to 60° C. for 2 minutes.
